(19) United States
(12) Patent Application Publication
(10) Pub. No.: US 2011/0171472 A1
(43) Pub. Date: Jul. 14, 2011

(54) Adhesive With a High Resistance

(75) Inventors: Marc Husemann, Hamburg (DE); Markus Brodbeck, Hamburg (DE)

(73) Assignee: TESA SE, Hamburg (DE)

(21) Appl. No.: 12/996,722

(22) PCT Filed: Aug. 26, 2009
(86) PCT No.: PCT/EP2009/061002

§ 371 Date: Mar. 25, 2011

(30) Foreign Application Priority Data
Sep. 11, 2008 (DE) 10 2008 053 447.1

(51) Int. Cl. B32B 7/12; B32B 37/12; B32B 37/14; H05K 3/00; B32B 27/38

(52) U.S. Cl. 428/413; 156/307.1; 428/521

(57) ABSTRACT

A method glues two plastic surfaces together with adhesion produced by a heat-activatable adhesive. The adhesive is a heat-activatable adhesive, which is based on i) at least one elastomer having a weight proportion of 30-70 wt. % ii) at least one reactive resin component having a weight proportion of 30-70 wt. %. At least one of the plastic surfaces that is to be glued is part of a substrate having a heat conductivity that is high enough to transfer the activation energy necessary for the adhesion to the heat-activatable adhesive.

This is a 371 of PCT/EP2009/061002 filed 26 Aug. 2009 (international filing date), and claims the priority of German Application No. 10 2008 053 447.1, filed on 11 Sep. 2008.

The invention relates to a heat-activatable adhesive with high repulsion resistance particularly at temperatures up to +85° C. and also to the use thereof in plastic/plastic bonds in electronic components for consumer goods.

For the adhesive bonding of plastics components in consumer electronics devices it is usual to use double-sided pressure-sensitive adhesive tapes. The bond strengths needed for this purpose are sufficient for fixing and fastening. For portable consumer electronics articles, however, the requirements are continually rising. On the one hand, these articles are becoming smaller and smaller, and so the bond areas as well are becoming smaller. On the other hand, the adhesive bond is required to meet additional requirements, since portable articles may be used across a relatively wide temperature range and, moreover, may be subjected to mechanical load (impacts, drops, etc.). A further trend is the use of flexible printed circuit boards. The advantage of these boards over their existing fixed counterparts is that they are significantly flatter and are able to combine a large number of flexible electrical components with one another. Thus FPCs (flexible printed circuits; flexible printed circuit boards) are frequently used to drive displays which, particularly in the case of notebooks and also in the case of flip cell phones, are flexible. Flexible printed circuit boards are also used to drive the camera lens or for backlighting units for LCD displays (liquid crystal displays, liquid-crystal data displays). The trend is intensifying the diversity of the designers, since there are more and more components that can be made flexible and yet remain electrically connectable. The use of flexible printed circuit boards, however, also necessitates new adhesive tape solutions, since flexible printed circuit boards are frequently fixed partially in the casing as well. For this purpose it is usual to use pressure-sensitive adhesives (PSAs) and/or double-sided pressure-sensitive adhesive tapes. Here, however, the challenges are relatively high, since the flexural stiffness of the flexible printed circuit board produces a constant repulsion force, which must be compensated by the PSA. A further factor is that consumer electronics devices are frequently also subjected to a climatic cycling test, in order to simulate external climatic effects. Here, typically, a temperature range from −40° C. to +85° C. is covered. Whereas lower temperatures do not constitute a problem, since in that case the PSA hardens and hence the internal strength goes up, high temperatures in particular are a problem, since in that case the PSAs become increasingly more fluid, lose internal strength, and the PSAs or pressure-sensitive adhesive tapes split cohesively under the repulsion force. In spite of this difficult environment, a multiplicity of pressure-sensitive adhesive tapes have already been developed. For example, from the company Nitto Denko, the products 5606R or 5608R are prized for such applications. In addition, the possibility exists of increasing the film thickness of the PSA or of the pressure-sensitive adhesive tape, since an increasing coatweight also entails an increase in adhesive strength.

A further possibility for the adhesive bonding of components in the consumer electronics segment is provided by heat-activatable films. Heat-activatable adhesives can be divided into two categories:

a) thermoplastic heat-activatable films
b) reactive heat-activatable films

Heat-activatable films have a particularly high bond strength, but must be activated by temperature. For this reason they are generally used for metal/metal or metal/plastic bonds. In such bonds the metal side allows introduction of the heat that is needed for activation. In the case of plastic/plastic bonds this is not possible, since plastics act as a thermal barrier and are typically deformed before the required heat reaches the heat-activatable adhesive.

The elucidations described show that, for the bonding of FPCs, there is a need for an adhesive or an adhesive tape that is able to absorb the repulsion force, and is able to do so even at film thicknesses below 100 μm, since the consumer electronics devices are becoming ever smaller and narrower.

The object of the invention, in light of this prior art, is that of providing an adhesive sheet for the fastening of flexible printed circuit boards to plastics components for portable consumer electronics articles, said sheet in particular
a) being capable of deployment from −40 to +85° C. and within this temperature range withstanding the repulsion force of the flexible printed circuit board
b) being distinguished by bond strengths of more than 15 N/cm to polyimide
c) being activatable by heat without superficial damage to the plastics to be bonded.

In accordance with the invention, this object is achieved by means of a method for the adhesive bonding of two plastics surfaces using an adhesive or an adhesive sheet comprising at least one heat-activatable adhesive.

At least one of the plastics surfaces in this case ought very preferably to belong to a substrate whose thermal conductivity is high enough to transfer the activation energy needed for adhesive bonding to the heat-activatable adhesive.

With great preference the adhesive is based on

i) an elastomer or two or more elastomers,
with a weight fraction of 30% to 70%, preferably 40%-60%;
ii) one or more reactive resin components, in other words one or more resins which are capable of crosslinking with themselves, with other reactive resins and/or with the elastomer,
with a weight fraction of 70% to 30%, preferably 60%-40%;
and
iii) optionally at least one tackifying resin
with a weight fraction of up to 20%.

In one favorable embodiment the adhesive is confined to the above-stated constituents, although in accordance with the invention it may also be advantageous if it comprises further constituents.

Elastomers are compounds of the kind defined in Römpp (Online Version; 2008 edition, document code RD-05-00596). Elastomers used in this case are preferably rubbers, polychloroisoprenes, polyacrylates, nitrile rubbers, epoxidized nitrile rubbers, etc.

Examples of suitable reactive resins include phenolic resins, epoxy resins, melamine resins, resins with isocyanate functions, or mixtures of the aforementioned resins. In combination with the reactive systems it is also possible to add a large number of other resins, filling materials, catalysts, ageing inhibitors, etc.

One very preferred group encompasses epoxy resins. The molecular weight of the epoxy resins varies from 100 g/mol up to a maximum of 10 000 g/mol for polymeric epoxy resins.

The epoxy resins comprise, for example, the reaction product of bisphenol A and epichlorohydrin, the reaction product of phenol and formaldehyde (novolak resins) and epichlorohydrin, glycidyl esters, and the reaction product of epichlorohydrin and p-aminophenol.

Preferred commercial examples are, for example, Araldite™ 6010, CY-281™, ECN™ 1273, ECN™ 1280, MY 720, RD-2 from Ciba Geigy, DER™ 331, DER™ 732, DER™ 736, DEN™ 432, DEN™ 438, DEN™ 485 from Dow Chemical, Epon™ 812, 825, 826, 828, 830, 834, 836, 871, 872, 1001, 1004, 1031 etc. from Shell Chemical, and HPT™ 1071, HPT™ 1079, likewise from Shell Chemical.

Examples of commercial aliphatic epoxy resins are, for example, vinylcyclohexane dioxides, such as ERL-4206, ERL-4221, ERL-4201, ERL-4289 or ERL-0400 from Union Carbide Corp.

As novolak resins, use may be made, for example, of Epi-Rez™ 5132 from Celanese, ESCN-001 from Sumitomo Chemical, CY-281 from Ciba Geigy, DEN™ 431, DEN™ 438, Quatrex 5010 from Dow Chemical, RE 305S from Nippon Kayaku, Epiclon™ N673 from DaiNipon Ink Chemistry, or Epicote™ 152 from Shell Chemical.

As reactive resins it is also possible, furthermore, to use melamine resins, such as Cymel™ 327 and 323 from Cytec, for example.

As reactive resins it is also possible, furthermore, to use terpene-phenolic resins, such as NIREZ™ 2019 from Arizona Chemical, for example.

As reactive resins it is also possible, furthermore, to use phenolic resins, such as YP 50 from Toto Kasei, PKHC from Union Carbide Corp. and BKR 2620 from Showa Union Gosei Corp., for example.

As reactive resins it is also possible, furthermore, to use polyisocyanates, such as Coronate™ L from Nippon Polyurethane Ind., Desmodur™ N3300 or Mondur™ 489 from Bayer, for example.

In order to accelerate the reaction between the two components, it is also possible to additize crosslinkers and accelerators into the mixture.

Examples of suitable accelerators include imidazoles, available commercially as 2M7, 2E4MN, 2PZ-CN, 2PZ-CNS, P0505, L07N from Shikoku Chem. Corp. or Curezol 2MZ from Air Products.

It is also possible, furthermore, to use amines, especially tertiary amines, for acceleration.

In a further preferred embodiment, poly(meth)acrylates are used as elastomers. Great preference is given to using polymers composed of polymers of at least the following monomers:
a1) 70% to 100% by weight of acrylic esters and/or methacrylic esters and/or their free acids with the following formula

CH₂═C(R₁)(COOR₂),
where R₁═H and/or CH₃ and R₂═H and/or alkyl chains having 1 to 30 C atoms.

For preparing the polymers, optionally, the following monomers are additionally added:
a2) up to 30% by weight of olefinically unsaturated monomers with functional groups.

In one very preferred version, monomers al) used are acrylic monomers comprising acrylic and methacrylic esters having alkyl groups consisting of 1 to 14 carbon atoms. Specific examples, without wishing to be restricted by this enumeration, are methyl acrylate, methyl methacrylate, ethyl acrylate, ethyl methacrylate, propyl acrylate, propyl methacrylate, n-butyl acrylate, n-butyl methacrylate, n-pentyl acrylate, n-hexyl acrylate, n-hexyl methacrylate, n-heptyl acrylate, n-octyl acrylate, n-nonyl acrylate, lauryl acrylate, stearyl acrylate, stearyl methacrylate, behenyl acrylate, and the branched isomers thereof, such as 2-ethylhexyl acrylate, for example. Further classes of compound for use, which may likewise be added in small amounts under al), are cyclohexyl methacrylates, isobornyl acrylate, and isobornyl methacrylates.

In one advantageous variant acrylic monomers corresponding to the following general formula are employed for a2):

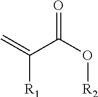

where R₁═H and/or CH₃ and the radical —OR₂ represents or includes a functional group which assists subsequent UV crosslinking of the pressure-sensitive adhesive—which for example, in one particularly preferred version, possesses an H donor effect.

Particularly preferred examples for component a2) are hydroxyethyl acrylate, hydroxypropyl acrylate, hydroxyethyl methacrylate, hydroxypropyl methacrylate, allyl alcohol, maleic anhydride, itaconic anhydride, itaconic acid, acrylamide, and glyceridyl methacrylate, benzyl acrylate, benzyl methacrylate, phenyl acrylate, phenyl methacrylate, tert-butylphenyl acrylate, tert-butylphenyl methacrylate, phenoxyethyl acrylate, phenoxyethyl methacrylate, 2-butoxyethyl methacrylate, 2-butoxyethyl acrylate, dimethylaminoethyl methacrylate, dimethylaminoethyl acrylate, diethylaminoethyl methacrylate, diethylaminoethyl acrylate, cyanoethyl methacrylate, cyanoethyl acrylate, glyceryl methacrylate, 6-hydroxyhexyl methacrylate, N-tert-butylacrylamide, N-methylolmethacrylamide, N-(butoxymethyl)methacrylamide, N-methylolacrylamide, N-(ethoxymethyl)acrylamide, N-isopropylacrylamide, vinylacetic acid, tetrahydrofurfuryl acrylate, β-acryloyloxypropionic acid, trichloroacrylic acid, fumaric acid, crotonic acid, aconitic acid, and dimethylacrylic acid, this enumeration not being conclusive.

In a further preferred version aromatic vinyl compounds are used for component a2), the aromatic nuclei being composed preferably of C₄ to C₁₈ units and being able also to include heteroatoms. Particularly preferred examples are styrene, 4-vinylpyridine, N-vinylphthalimide, methylstyrene, 3,4-dimethoxystyrene, and 4-vinylbenzoic acid, this enumeration not being conclusive.

For the polymerization the monomers are chosen such that the resultant polymers can be employed as heat-activatable adhesives, especially such that the resultant polymers have adhesive properties in accordance with the “Handbook of Pressure Sensitive Adhesive Technology” by Donatas Satas (van Nostrand, N.Y. 1989). For these applications the static glass transition temperature of the resultant polymer (including the added resins or other additives) is advantageously above 30° C.

In order to achieve a polymer glass transition temperature T_{g,A} of T_{g,A}≧30° C., in accordance with the remarks above, the monomers are very preferably selected, and the quantitative composition of the monomer mixture advantageously chosen, such that according to the Fox equation (E1) (cf. T. G. Fox, Bull. Am. Phys. Soc. 1 (1956) 123) the desired T_{g,A} value is produced for the polymer.

$$\frac{1}{{T}_{g}} = {\sum }_{n} \frac{{w}_{n}}{{T}_{g , n}} \qquad ( E1 )$$

In this equation n represents the serial number of the monomers employed, wₙ the mass fraction of the respective monomer n (% by weight), and T_{g,n} the respective glass transition temperature of the homopolymer of the respective monomers n, in K.

### Preparation Method

For further processing and for adhesive bonding, the heat-activatable adhesive is made available on a release paper or release film.

Coating may take place from solution or from the melt. In the case of coating from solution it is preferred to operate—as is customary for the processing of adhesives from solution—with the doctor technique, in which case all of the doctor techniques known to the skilled worker may be used. For application from the melt, if the polymer is present in solution, the solvent is stripped off under reduced pressure, preferably in a concentrating extruder, for which purpose, for example, single-screw or twin-screw extruders may be used, these extruders preferably distilling off the solvent in different vacuum stages or the same vacuum stage, and possessing a feed preheater. Coating then takes place via a melt die or extrusion die, and the adhesive film, if desired, is stretched in order to achieve the optimum coating thickness. For the mixing of the resins it is possible to use a compounder or a twin-screw extruder for mixing.

Temporary carrier materials used for the adhesive are the materials that are customary and familiar to the skilled worker, such as films (polyester, PET, PE, PP, BOPP, PVC, polyimide) and release papers (glassine, HDPE, LDPE). The carrier materials ought to be provided with a release layer. In one very preferred version of the invention, the release layer is composed of a silicone release varnish or a fluorinated release varnish.

The method of the invention is outstandingly suitable for bonding flexible printed circuit boards, especially in plastics casings of electronic components or devices. The thermal conductivity of the flexible printed circuit board is high enough to transfer the activation energy needed for adhesive bonding to the heat-activatable adhesive.

### BRIEF DESCRIPTION OF THE DRAWINGS

FIG. 1 illustrates a product construction in an embodiment of the present invention.

FIG. 2 illustrates a product construction in an embodiment of the present invention.

FIG. 3 illustrates an adhesive bonding of a flexible printed circuit board in an embodiment of the present invention.

### PRODUCT CONSTRUCTIONS

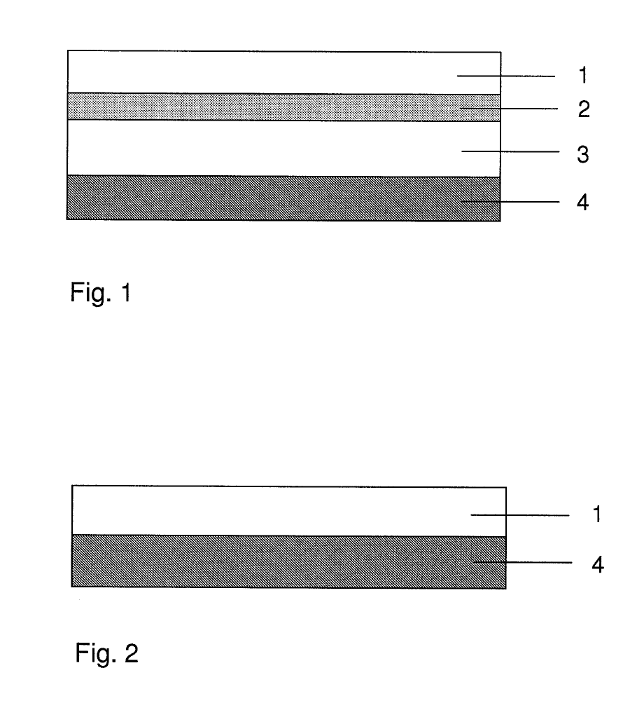

The heat-activatable sheets preferably have the product design shown in FIG. 1, where:
1=heat-activatable adhesive
2=carrier material
3=heat-activatable adhesive
4=temporary carrier

The product construction shown in FIG. 1 comprises the double-sided coating of the heat-activatable adhesive (1, 3) on a carrier material (2). The overall assembly is protected preferably with at least one temporary carrier (4), in order to allow the heat-activatable adhesives to be unwound from the roll. In a further embodiment, the two sides of adhesive (1, 3) are lined with a temporary carrier (not shown here). A further possibility is for carrier material (2) to be provided with one or more functional coatings (for example, primer, adhesion promoter, etc.). The layers of adhesive on both sides of the carrier material (2) may be identically equipped; it is, however, also possible for the two layers of adhesive to differ, in respect in particular of their chemical compositions and/or thicknesses.

The amount of adhesive applied per side is preferably between 5 and 250 g/m².

The product construction shown in FIG. 2 comprises the single-sided coating of the heat-activatable adhesive on a temporary carrier. The definition of the positional numbers corresponds in this case to that for FIG. 1 (1=heat-activatable adhesive, 4=temporary carrier). The heat-activatable adhesive (1) is preferably lined with at least one temporary carrier (4), in order to allow the unwinding of the adhesive tape or to improve the punching characteristics. In a further embodiment, both sides are lined with a temporary carrier (not shown here). The amount of adhesive applied is preferably between 5 and 250 g/m².

As carrier material it is possible in this case to use the materials that are customary and are familiar to the skilled worker, such as films (polyester, PET, PE, PP, BOPP, PVC, polyimide, polymethacrylate, PEN, PVB, PVF, polyamide), nonwovens, foams, woven fabrics, and woven films.

### Use:

Flexible printed circuit boards are present in a large number of electronic devices, such as mobile telephones, autoradios, computers, etc., for example. Generally speaking, they consist of layers of copper or aluminum (electrical conductor) and polyimide (electrical insulator). Other plastics as well, however, are used as the electrical insulator, such as polyethylene naphthalate (PEN) or liquid crystal polymers (LCP), for example. In view of the fact that they connect flexible electrical components to one another, they must be flexible in design. Since, however, two or more electrical components must always be bonded to one another, the calculating performance of the flexible printed circuit boards is increasing, resulting in multilayer embodiments. The layer thickness of the flexible printed circuit board may therefore vary from 50 μm to 500 μm. Since the flexible printed circuit board is composed of an assembly of insulator and electrical conductor, and both materials have different properties, the flexural stiffness of flexible printed circuit boards is relatively high. It may be increased still further by the population of the boards, with ICs, for example, or as a result of partial reinforcements. In order then to prevent uncontrolled movements, or to minimize the space requirements, flexible printed circuit boards are bonded within the casing of electronic devices. In this case, in general, there are different plastics available as materials for bonding. Thus, very frequently, polycarbonates (PC), ABS, ABS/PC blends, polyamides, glass fiber-reinforced polyamides, polyethersulfones, polystyrene or the like are used. Although not used in the sense of the invention, it is, however, also possible for glass or metals to be used as substrates, such as aluminum or stainless steel, for example.

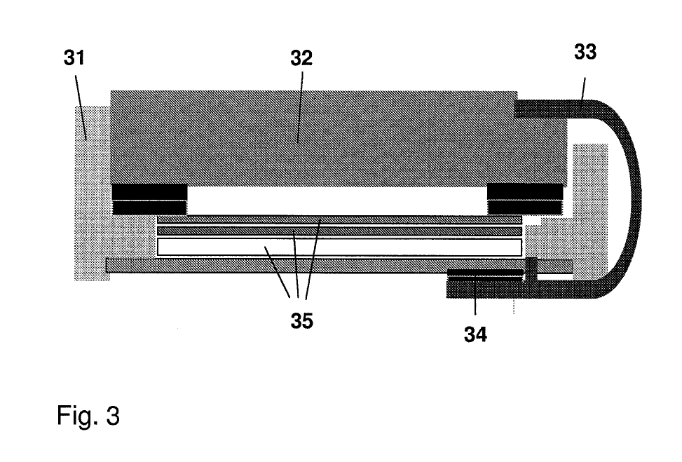

One typical use is represented by the adhesive bonding, shown in FIG. 3, of flexible printed circuit boards to the backlighting of LCD displays. Owing to the narrow flexing, a constant flexural force is developed, and must be absorbed by the heat-activatable adhesive. In application in electronic components, flexible printed circuit boards typically have a flexural angle of at least 90°, more particularly of 180°.

FIG. 3 shows an example of the adhesive bonding of a flexible printed circuit board with a heat-activatable adhesive, the flexural angle of the flexible printed circuit board being 180°. The definitions in this figure are as follows:
31=casing for the backlighting
32=LCD panel
33=flexible printed circuit board
34=heat-activatable adhesive or heat-activatable adhesive tape (inventive use)
35=optical films.

In addition it is necessary to take account of the fact that, frequently, the electronic devices are exposed to fluctuating conditions. This means, in an extreme case, that the bond strength even at 85° C. must be high enough to prevent detachment of the flexible printed circuit board.

Moreover, the heat-activatable film ought to be amenable to processing within a relatively narrow operational window, so that, on the one hand, sufficiently high stiffness must still be retained at 85° C., but temperature activation must be possible as well. The substrates to be bonded are frequently temperature-stable only up to 130° C. Another factor to be taken into account is that the flexible printed circuit boards are already populated with electronics, which are likewise temperature-sensitive. This distinguishes the operation from, for example, the adhesive bonding of stiffening materials for partial stiffening, which takes place during the actual operation of fabricating the flexible printed circuit board. Lastly, it must likewise be taken into account that the high unit numbers place limits on the processing window—that is, the heat must be introduced relatively quickly.

### Adhesive Bonding:

### Prelamination

Typically, diecuts are produced by punching from the heat-activatable adhesive, and are placed onto the plastics part. In the simplest case, the diecut is placed on the plastics part manually, with tweezers, for example. The formation of the diecut may differ. Moreover, for constructional reasons, it may also be necessary to use full-area diecuts. In a further version, the heat-activatable adhesive tape diecut is treated, after manual positioning, with a heat source, in the simplest case, for example, with an iron. This increases the adhesion to the plastic. For this purpose it is also of advantage if the diecut is also equipped with a temporary carrier.

In the prior art, adhesive bonds are typically performed on metal substrates. In that case, the metal part is first placed onto the heat-activatable adhesive tape diecut. Placement takes place on the open side. The reverse side still has the temporary carrier located there. Subsequently, by means of a heat source, heat is introduced through the metal into the heat-activatable adhesive tape. This makes the adhesive tape tacky, and it adheres more strongly to the metal than to the temporary carrier.

For the method of the invention, the amount of heat must be well dosed. In the case of reactive systems, there ought to be an upper limit on the temperature, so that during prelamination there is no crosslinking reaction to lessen the ultimate bonding performance later on. For the introduction of the heat, in one preferred version, a heating press is used. The ram of the heating press is made, for example, of aluminum, brass or bronze, and it takes on the external form of the diecut. The ram may also have shaping, in order, for example, to prevent partial heat damage. The pressure and the temperature are introduced uniformly as far as possible. Pressure, temperature, and time are adapted to the materials (metal, metal thickness, type of heat-activatable film) and varied.

The typical operational window for the prelamination is situated at 1.5 to 10 seconds' activation time, 1.5 bar to 5 bar applied pressure, and 100° C. to 150° C. heating ram temperature.

### Adhesive Bonding of the Substrates

The operation of adhesive bonding between the flexible printed circuit board and the plastics part is carried out preferably with a heating press. For this purpose, the heat is introduced preferably from the side of the flexible printed circuit board, since it is the board which in general has the better thermal conductivity.

Generally speaking, pressure and temperature are applied simultaneously. This is done by means of a heating ram which is composed of a material having good thermal conductivity. Examples of typical materials are copper, brass, bronze or aluminum. However, other alloys can also be used. Furthermore, the ram of the heating press ought preferably to adopt the shape of the top face of the bond area. This shape may in turn be 2-dimensional or 3-dimensional in nature. It is common to apply the pressure via a pressure cylinder. Application, however, need not necessarily take place via air pressure. Also possible, for example, are hydraulic press devices or electromechanical press devices (spindles, actuating drives or actuating elements). It may further be of advantage to introduce pressure and temperature multiply, in order, for example, to increase the operational throughput by means of series connection or a rotation principle. In this case, the rams of the heating press need not all be operated with the same temperature and/or with the same pressure. Furthermore, it is also possible—although not always of advantage—for the contact time to be different. Furthermore, it may also be of advantage, in a final operating step, to introduce only pressure, with a press ram cooled to room temperature or with a cooled press ram.

The operating times usually run to 2.5 to 30 seconds per press ram step. In the case of reactive heat-activatable films in particular it may be of advantage to carry out bonding at relatively high temperatures and also for relatively long times. Furthermore, it may also be necessary to vary the pressure. Very high pressures may cause squeezing of the heat-activatable film. It is desirable, generally speaking, to minimize such squeezing. Suitable pressures run to 1.5 to 10 bar, calculated on the bond area. Here again, the stability of the materials and also the flow behavior of the heat-activatable film exert a large influence on the pressure to be selected.

### Experimental Section

### Test Methods:

### Repulsion Test A

A 100 μm thick polyimide film is cut out as a flexible printed circuit board substitute in 10 cm×1 cm. One end of the polyimide film is then bonded to a polycarbonate (3 mm thickness, 1 cm width, 3.5 cm length). Adhesive bonding is carried out using Tesa® 4965. The polyimide film is then bent in a loop around the polycarbonate plate, and bonded at a distance of 20 mm from the end with the heat-activatable film. For the adhesive bond, the heat-activatable film has a width of 10 mm and a length of 3 mm. After adhesive bonding, the assembly is stored in a drying cabinet at 85° C. or at −40° C. It passes the test if reliably, within 72 hours, the bond is not parted by the flexural stiffness of the polyimide film.

### 90° Bond Strength Test B

With the heat-activatable film, a strip of polyimide film 1 cm wide, 100 μm thick, and 10 cm long is bonded to a polycarbonate plate 3 mm thick, 5 cm wide, and 20 cm long. Subsequently, using a tensile testing machine from Zwick, the polyimide film is peeled at a constant peel angle of 90° and at a speed of 50 mm/min, and the force in N/cm is recorded. The measurement is carried out at 23° C. under 50% humidity. The measurement values are determined in triplicate and averaged.

### Adhesive Bonding

The adhesive bonding of the reactive heat-activatable films was carried out in a heating press with a ram temperature of 180° C., a contact time of 30 seconds, and a pressure of 8 bar.

### Reference Example 1

Dynapol® S EP 1408 (copolyester from Evonik, melting temperature 80° C.) was pressed out to 100 μm at 140° C. between two plies of siliconized glassine release paper. The crossover determined in accordance with test method C is 91° C.

### Reference Example 2

Dynapol® S 361 (copolyester from Evonik, melting temperature 175° C.) was pressed out to 100 μm at 230° C. between two plies of siliconized glassine release paper. The crossover determined in accordance with test method C is 178° C.

### Reference Example 3

Tesa® 4982 (100 μm thickness, 12 μm PET carrier, resin-modified acrylate PSA, 2×46 g/m²) was included in the investigation as a PSA. The product was applied at 23° C., but with 5 bar pressure and 10 seconds' bonding time.

### Example 1

50% by weight of Breon N36 C80 (nitrile rubber) from Zeon, 40% by weight of phenolic novolak resin Durez® 33040 blended with 8% HMTA (Rohm and Haas), and 10% by weight of the phenolic resol resin 9610 LW from Bakelite were prepared as a 30% strength solution in methyl ethyl ketone in a compounder. The kneading time was 20 hours. The heat-activatable adhesive was subsequently coated from solution onto a glassine release paper and dried at 100° C. for 10 minutes. After drying, the coat thickness was 100 μm.

### Example 2

50% by weight of Nipol N1094-80 (nitrile rubber) from Zeon, 40% by weight of phenolic novolak resin Durez® 33040 blended with 8% HMTA (Rohm and Haas), and 10% by weight of the phenolic resol resin 9610 LW from Bakelite were prepared as a 30% strength solution in methyl ethyl ketone in a compounder. The kneading time was 20 hours. The heat-activatable adhesive was subsequently coated from solution onto a glassine release paper and dried at 100° C. for 10 minutes. After drying, the coat thickness was 100 μm.

### Results

First of all, the repulsion test A was carried out with all the examples. The results are set out in Table 1.

TABLE 1

| | Repulsion test A | Repulsion test A |
|---|---|---|
| Examples | (85° C.) | (−40° C.) |
| 1 | >72 hours | >72 hours |
| 2 | >72 hours | >72 hours |
| Reference 1 | 6 hours** | >72 hours |
| Reference 2 | not determined* | not determined* |
| Reference 3 | 2 hours** | >72 hours |

*Heat-activatable film could not be melted
**The adhesive bond opened within this time period

The results show that, with the heat-activatable examples 1 and 2, a very good repulsion resistance can be achieved at 85° C. and at −40° C. In all cases the bond held for more than 72 hours. Reference example 3, in contrast, shows that PSAs are not very suitable. There, the bond opened within just 2 hours at 85° C. Reference example 2 could not be melted under the standard conditions. Only after the temperature was increased to 210° C. was melting achieved. At these temperatures, however, there was already deformation of the polycarbonate, and so this thermoplastic cannot be applied without damage to the substrates. Reference example 1 here showed a significantly easier melting, but the bond opened at 85° C. after just 6 hours. The thermoplastic is too soft for this application.

In a further test, the bonding strength was determined by test method B. The results are summarized in Table 2.

TABLE 2

| Examples | 90° bond strength test B |
|---|---|
| 1 | 16.9 N/cm |
| 2 | 18.2 N/cm |
| Reference 1 | 17.4 N/cm |
| Reference 2 | not determined |
| Reference 3 | 7.2 N/cm |

* Heat-activatable film could not be melted

The values from Table 2 show that, with all of the inventive examples 1 and 2, very high bonding strengths were achieved and hence effective adhesion was built up on polyimide and on polycarbonate. Reference example 3 makes it clear that significantly lower bonding strengths are obtained with PSAs.

Reference example 2 could not be melted under the standard conditions. Only after the temperature was increased to 210° C. was melting achieved. At these temperatures, however, there was already deformation of the polycarbonate, and so this thermoplastic cannot be applied without damage to the substrates.

From the measurement values it can be inferred that all of the inventive examples meet the most important criteria for flexible printed circuit board bonding. The inventive examples are therefore very highly suited to this application.

We claim:

1. A method for the adhesive bonding of two plastics surfaces to one another, the adhesive bonding being brought about by a heat-activatable adhesive, wherein
said heat-activatable adhesive is based on
i) at least one elastomer with a weight fraction of 30% to 70% by weight
ii) at least one reactive resin component with a weight fraction of 30% to 70% by weight
where
at least one of the plastics surfaces to be bonded belongs to a substrate whose thermal conductivity is high enough to transfer an activation energy necessary for adhesive bonding to the heat-activatable adhesive.

2. The method according to claim 1, wherein the adhesive comprises
iii) up to 20% by weight of one or more tackifying resins.

3. The method according to claim 1, wherein one of the plastics surfaces to be bonded belongs to a flexible printed circuit board.

4. The method according to claim 3, wherein the flexible printed circuit board has a flexural angle of at least 90°.

5. The method according to claim 1, wherein the at least one elastomer is selected from the group encompassing rubbers, polychloroisoprenes, polyacrylates, and nitrile rubbers.

6. The method according to claim 1, wherein the at least one reactive resin component is selected from the group of reactive resins encompassing phenolic resins, epoxy resins, melamine resins, and novolak resins.

7. The method according to claim 1, wherein transfer of the activation energy for adhesive bonding, and the adhesive bonding, take place within a period of not more than 30 seconds.

8. An adhesive bond obtainable by the method according to claim 1.

9. The method according to claim 4, wherein the flexural angle is 180°.
